(19) United States
(12) Patent Application Publication
(10) Pub. No.: US 2023/0326912 A1
(43) Pub. Date: Oct. 12, 2023

(54) MULTI-CHIP 3D STACKING PACKAGING STRUCTURE AND PACKAGING METHOD WITH HIGH HEAT DISSIPATION EFFICIENCY

(71) Applicant: SHANDONG HANTURE TECHNOLOGY CO., LTD, Zaozhuang (CN)

(72) Inventors: LINGGANG LIU, Zaozhuang (CN); HUI XU, Zaozhuang (CN); HANG ZHANG, Zaozhuang (CN)

(21) Appl. No.: 17/719,233

(22) Filed: Apr. 12, 2022

(51) Int. Cl. H01L 25/10

(52) U.S. Cl. CPC H01L 25/105; H01L 2225/1094; H01L 2225/1023

(57) ABSTRACT

A multi-chip 3D stacking packaging structure with high heat dissipation efficiency comprises a wiring board, a power device fixed on the wiring board, wherein a lateral heat insulating plate is arranged around the horizontal plane of the power device. A heat insulating layer is arranged directly above the power device, and the height of the heat insulating layer is higher than that of the lateral heat insulating plate. A power heat dissipation shoulder is arranged on the top of the lateral heat insulating plate, and the top of the power heat dissipation shoulder is connected with the edge of the heat insulating layer, The wiring hoard, the lateral heat insulating plate, the heat insulating layer on the top of the power device and the power heat dissipation shoulder together form a first closed heat-generating space cavity. A long adapter support channel is arranged on the wiring board.

### TECHNICAL FIELD

The present application discloses a multi-chip 3D stacking packaging structure and packaging method with high heat dissipation efficiency.

### BACKGROUND

The related prior art discloses a multi-chip 3D stacking packaging technology with high heat dissipation efficiency, which thermally isolates the power device from the functional chip by arranging heat insulating elements around the power device, and prevents the heat generated by the power device from being transferred laterally to chips on the same layer; and an adapter plate is arranged on the chip packaging structure in the same layer of the chip, and a micro-flow channel formed with a liquid flow circuit is arranged in the adapter plate. The micro-flow channel prevents the power device from transferring heat to the upper chip, and at the same time can take away the heat generated by the upper chip and the power device, so that the power device forms an isolated heat source island for active heat dissipation. In a specific technology, the multi-chip 3D stacking packaging structure with high heat dissipation efficiency as shown in FIG. 1 comprises: a redistribution layer 10; a first chip 20, the first chip 20 is arranged on the redistribution layer 10, and connected with the redistribution layer 10; a power device 30, which is also arranged on the redistribution layer 10 and is electrically connected to the redistribution layer 10; a first heat insulating element 40, the first heat insulating element 40 is located on the redistribution layer 10 and is arranged between the power device 30 and the first chip 20; a first packaging layer 50, the first packaging layer 50 is arranged on the redistribution layer 10, and encapsulates the first chip 20, the first heat insulating element 40 and the power device 30; an adapter plate 60, the adapter plate 60 is arranged on the first packaging layer 50, and a second heat insulating element is arranged inside the adapter plate 60; a second chip 70, the second chip 70 is arranged on the adapter plate 60 and is electrically connected to the redistribution layer 10; a second encapsulating layer 80, the second encapsulating layer 80 is arranged on the adapter plate 60 and encapsulates the second chip 70. At present, it is very mature to complete the multi-chip 3D stacking package through the above-mentioned basic structure in the prior art. However, the actual heat dissipation effect of the above basic structure is not ideal. The heat dissipation principle of the above-mentioned basic structure is to thermally isolate the power device from the functional chip by arranging heat insulating elements around the power device in the horizontal direction, thus blocking the heat dissipation of the power device in the horizontal direction. However, in actual power devices, the upward heat dissipation is more obvious. For this problem, in the above-mentioned basic structure, a micro-flow channel for heat dissipation is arranged on the power device, but the heat dissipation of the power device is not stable in actual work, and overheating often occurs. In this case, there is often a problem that the heat generation power of the power device is much higher than the heat dissipation power of the micro-flow channel, so the excessive heat generation of the power device will directly affect the upper chip. In fact, the upper chip itself also generates heat. Even though most of the heat generated by the upper chip will be dissipated upward, the upper and lower parts of the upper chip will be heated due to excessive heat generation of the power device, which will have a greater impact on the upper chip.

### SUMMARY

In order to overcome the above-mentioned defects of the prior art, the embodiments of the present application provide a multi-chip 3D stacking packaging structure and packaging method with high heat dissipation efficiency, so as to solve the above-mentioned problems in the background art.

To achieve the above purpose, the application provides the following technical solutions: a multi-chip 3D stacking packaging structure with high heat dissipation efficiency, comprising a wiring board, a power device fixed on the wiring board, and a lateral heat insulating plate is arranged around the horizontal plane of the power device, wherein a heat insulating layer is arranged directly above the power device, and the height of the heat insulating layer is higher than that of the lateral heat insulating plate, a power heat dissipation shoulder is arranged on the top of the lateral heat insulating plate, and the top of the power heat dissipation shoulder is connected with the edge of the heat insulating layer, the wiring board at the bottom of the power device, the lateral heat insulating plate arranged around the horizontal plane of the power device, the heat insulating layer on the top of the power device and the power heat dissipation shoulder together form a closed first heat-generating space cavity, a long adapter support channel is arranged on the wiring board on the side of the horizontal surface of the lateral heat insulating plate that is away from the power device, a first adapter plate is arranged on the top of the long adapter support channel, the top of the first adapter plate is fixed with a second adapter plate through the short adapter support channel, and the top of the second adapter plate is fixed. with a common chip, the common chip is electrically connected to an adapter metal wire through the second adapter plate, and the adapter metal wire is electrically connected to the wiring board through the short adapter support channel, the first adapter plate, and the long adapter support channel.

In a preferred embodiment, a second heat dissipation shoulder is arranged on the edge of the first adapter plate, and the top of the second heat dissipation shoulder is connected to the top of the second adapter plate.

In a preferred embodiment, a chip enclosing plate is arranged around horizontal plane of the common chip, and a chip top plate is arranged directly above the common chip, and the height of the chip top plate is higher than that of the chip enclosing plate, a first heat dissipation shoulder is arranged on the top of the chip enclosing plate, and the top of the first heat dissipation shoulder is connected to the chip top plate, the second adapter plate at the bottom of the common chip, the chip enclosing plate arranged around the horizontal plane of the common chip, the chip top plate on the top of the common chip, and the first heat dissipation shoulder together form a closed second heat-generating space cavity.

In a preferred embodiment, the chip top plate is provided with a heat insulating layer when the chip is arranged directly above the common chip.

In a preferred embodiment, the chip top plate is provided with a heat dissipation package layer, when no chip is arranged directly above the common chip.

In a preferred embodiment, the power heat dissipation shoulder and the second heat dissipation shoulder comprise several micro-flow channels, wherein the number and size of pipes of the micro-flow channels of the power heat dissipation shoulder and the second heat dissipation shoulder are configured together to ensure that the power heat dissipation shoulder meets the minimum heat dissipation requirement of the first heat-generating space cavity, that is, first determine the limit heat-generating power P_{M} of the first heat-generating space cavity;
determine the self-heat dissipation power paᵢ of each pipe in its micro-flow channels for the power heat dissipation shoulder, determine the external heat dissipation power pbᵢ of each pipe in its micro-flow channels for the power heat dissipation shoulder, and determine the number n1 of pipes in its micro-flow channels for the power heat dissipation shoulder; determine a self-heat dissipation power pcᵢ of each pipe in its micro-flow channels for the second heat dissipation shoulder, determine an external heat dissipation power pdᵢ of each pipe in its micro-flow channels for the second heat dissipation shoulder, and determine the number n2 of pipe in its micro-flow channels of the second heat dissipation shoulder; then determine the thermal energy power attenuation rate f1 from a spatial position of the power heat dissipation shoulder to a spatial position of the second heat dissipation shoulder; then, the number and size of the pipes in its the micro-flow channel of the power heat dissipation shoulder and the second heat dissipation shoulder that are configured together specifically meet:

P_{M}*M1−Σᵢ₌₁ⁿ¹(paᵢ+pbᵢ)≤0;

(P_{M}=Σᵢ₋₁ⁿ¹(pcᵢ+pdᵢ))*)1−f1)*M2≤Σᵢ₌₁ⁿ¹(paᵢ+pbᵢ);

where i is a variable, M1 is the first acceptable parameter, M2 is the second acceptable parameter, the first acceptable parameter represents the ratio of the limit heat-generating power of the first heat-generating space cavity to the maximum power of an acceptable thermal environment in the first heat-generating space cavity, the second acceptable parameter represents the ratio of the power of indirect heating of other devices by the remaining heat after the heat generated in the first heat-generating space cavity is dissipated by the second heat-dissipating shoulder to the maximum power of the thermal environment acceptable to the other devices.

In a preferred embodiment, the power heat dissipation shoulder and the second heat dissipation shoulder comprise several micro-flow channels, wherein the number and size of pipes of the micro-flow channels of the power heat dissipation shoulder and the second heat dissipation shoulder are configured together to ensure that the power heat dissipation shoulder meets the minimum heat dissipation requirement of the first heat-generating space cavity, that is, first determine the limit heat-generating power PM of the first heat-generating space cavity;
determine the convolution equivalent efficiency peᵢ of the self-heat dissipation power paᵢ of each pipe in its micro-flow channels and the external heat dissipation power pbᵢ of each pipe in its micro-flow channels for the power heat dissipation shoulder, and determine the number n1 of micro-flow channels of the power heat dissipation shoulder; determine the convolution equivalent efficiency prᵢ of the self-heat dissipation power pcᵢ of each pipe in its micro-flow channels and the external heat dissipation power pdᵢ of each pipe in its micro-flow channels for the second heat dissipation shoulder, and the number n2 of the pipes of micro-flow channels of the second heat dissipation shoulder; then determine the thermal energy power attenuation rate f1 from a spatial position of the power heat dissipation shoulder to a spatial position of the second heat dissipation shoulder; then, the number and size of the pipes in its the micro-flow channel of the power heat dissipation shoulder and the second heat dissipation shoulder that are configured together specifically meet:

PM*M1=Σᵢ₌₁ⁿ¹(peᵢ)≤0;

(PM−Σᵢ₌₁ⁿ¹(prᵢ))*(1−f1)*M2≤Σᵢ₌₁ⁿ¹(peᵢ);

where i is a variable, M1 is the first acceptable parameter, M2 is the second acceptable parameter, the first acceptable parameter represents the ratio of the limit heat-generating power of the first heat-generating space cavity to the maximum power of an acceptable thermal environment in the first heat-generating space cavity, the second acceptable parameter represents the ratio of the power of indirect heating of other devices by the remaining heat after the heat generated in the first heat-generating space cavity is dissipated by the second heat-dissipating shoulder to the maximum power of the thermal environment acceptable to the other devices.

The present application also discloses a packaging method of the multi-chip 3D stack packaging structure with high heat dissipation efficiency, the packaging method comprises the following steps: arranging a power device on a wiring board, arranging a lateral heat insulating plate around the horizontal plane of the power device, and then arranging a power heat dissipation shoulder on the top of the lateral heat insulating plate, and then arranging a heat insulating layer between the power heat dissipation shoulders, after that, arranging a long adapter support channel on the wiring board on the side of the horizontal plane of the lateral heat insulating plate that is away from the power device, and reserving an adapter metal wire on the long adapter support channel; arranging a first adapter plate, a short adapter support channel and a second adapter plate on the top of the long transfer support channel, reserving adapter metal wires on the short adapter support channel and a first adapter plate; arranging a second heat dissipation shoulder between the first adapter plate and the second adapter plate; and then arranging common chip, chip enclosing plate, first heat dissipation shoulder and chip top plate on the second adapter plate.

Technical effects and advantages of this application: in the present application, the heat insulating layer 108 is arranged directly above the power device, so that the present application can directly isolate the first heat-generating space cavity from the common chip, and avoid the problem that excessive heat generation of the power device directly affects the upper chip in the prior art. In the present application, by cleverly arranging the power heat dissipation shoulder, the dissipated heat can be guided to the edge of the device, which not only has a good heat dissipation effect, but also can more efficiently dissipate excessive heat generation to the outside of the device. The heat is neither spread directly above nor to the side of the chip, but is spreads diagonally above. In more specific implementation, the present application can ensure that the heat dissipation of the power device will not have an indirect impact on other devices on the basis of not exceeding the maximum power of the acceptable thermal environment in the first heat-generating space cavity. That is to say, even if the heat dissipation of the power device will indirectly affect other devices, it is within the acceptable range of other devices.

### BRIEF DESCRIPTION OF DRAWINGS

FIG. 1 is a schematic diagram of the overall structure of the prior art.

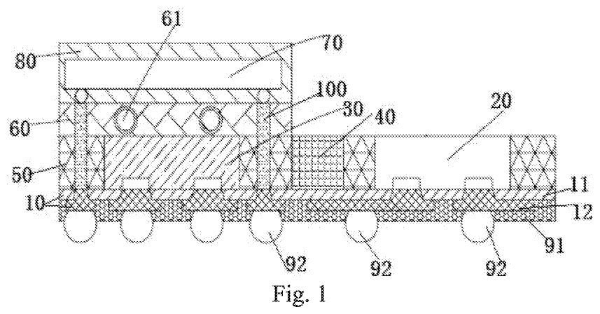

FIG. 2 is a schematic structural diagram of an embodiment of the present application.

FIG. 3 is a schematic structural diagram of an embodiment of the present application.

common chip 200; power device 300; chip top plate 101; first heat dissipation shoulder 102; chip enclosing plate 103; second adapter plate 104; first adapter plate 105; second heat dissipation shoulder 106; heat insulating layer 108; long adapter support channel 109; power heat dissipation shoulder 110; lateral heat insulating plate 11.1; adapter metal wire 160; wring board 161; micro-flow channel 601.

### DETAILED DESCRIPTION

The technical solutions in the embodiments of the present application will be clearly and completely described below with reference to the drawings in the embodiments of the present application. Obviously; the described embodiments are only a part of the embodiments of the present application, but not all of the embodiments. Based on the embodiments in the present application, all other embodiments obtained by those of ordinary skill in the art without creative efforts shall fall within the protection scope of the present application.

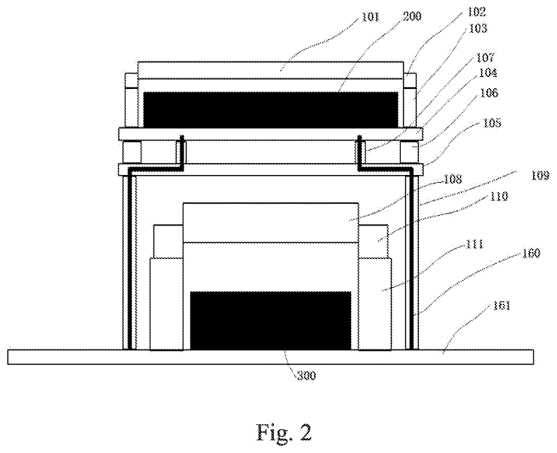

in a specific embodiment, the multi-chip 3D stacking packaging structure with high heat dissipation efficiency of the present application., as shown in. FIG. 2, comprising a wiring board 161, a power device 300 fixed on the wiring board 161, and a lateral heat insulating plate 111 is arranged around the horizontal plane of the power device 300, wherein a heat insulating layer 108 is arranged directly above the power device 300, and the height of the heat insulating layer 108 is higher than that of the lateral heat insulating plate 111, a power heat dissipation shoulder 110 is arranged on the top of the lateral heat insulating plate 111 and the top of the power heat dissipation shoulder 110 is connected with the edge of the heat insulating layer 108, the wiring board 161 at the bottom of the power device 300, the lateral heat insulating plate 111 arranged around the horizontal plane of the power device 300, the heat insulating layer 108 on the top of the power device 300 and the power heat dissipation shoulder 110 together form a closed first heat-generating space cavity, a long adapter support channel 109 is arranged on the wiring board 161 on the side of the horizontal surface of the lateral heat insulating plate 111 that is away from the power device 300, a first adapter plate 105 is arranged on the top of the long adapter support channel 109, the top of the first adapter plate 105 is fixed with a second adapter plate 104 through a short adapter support channel 107, and the top of the second adapter plate 104 is fixed with a common chip 200, the common chip 200 is electrically connected to an adapter metal wire 160 through the second adapter plate 104, and the adapter metal wire 160 is electrically connected to the wiring board 161 through the short adapter support channel 107, the first adapter plate 105, and the long adapter support channel 109.

In a specific embodiment, a packaging method of the multi-chip 3D stack packaging structure with high heat dissipation efficiency comprises the following steps: arranging a power device 300 on a wiring board 161, arranging a lateral heat insulating plate 111 around the horizontal plane of the power device 300, and then arranging a power heat dissipation shoulder 110 on the top of the lateral heat insulating plate 111, and then arranging a heat insulating layer 108 between the power heat dissipation shoulders 110, after that, arranging a long adapter support channel 109 on the wiring board 161 on the side of the horizontal plane of the lateral heat insulating plate 111 that is away from the power device 300, and reserving an adapter metal wire 160 on the long adapter support channel 109; arranging a first adapter plate 105, a short adapter support channel 107 and a second adapter plate 104 on the top of the long transfer support channel 109, reserving adapter metal wires 160 on the short adapter support channel 107 and the first adapter plate 105; arranging a second heat dissipation shoulder 106 between the first adapter plate 105 and the second adapter plate 104; and then arranging common chip 200, chip enclosing plate 103, first heat dissipation shoulder 102 and chip top plate 101 on the second adapter plate 104.

in the present application, the heat insulating layer 108 is arranged directly above the power device, so that the present application can directly isolate the first heat-generating space cavity from the common chip, and avoid the problem that excessive heat generation of the power device directly affects the upper chip in the prior art. In the present application, by cleverly arranging the power heat dissipation shoulder, the dissipated heat can be guided to the edge of the device, which not only has a good heat dissipation effect, hut also can more efficiently dissipate excessive heat generation to the outside of the device. The heat is neither spread directly above nor to the side of the chip, but is spreads diagonally above.

In a preferred embodiment, a second heat dissipation shoulder 106 is arranged on the edge of the first adapter plate 105, and the top of the second heat dissipation shoulder 106 is connected to the top of the second adapter plate 104.

In a preferred embodiment, a chip enclosing plate 103 is arranged around. horizontal plane of the common chip 200, and a chip top plate 101 is arranged directly above the common chip 200, and the height of the chip top plate 101 is higher than that of the chip enclosing plate 103, a first heat dissipation shoulder 102 is arranged on the top of the chip enclosing plate 103, and the top of the first heat dissipation shoulder 102 is connected to the chip top plate 101, the second adapter plate 104 at the bottom of the common chip 200, the chip enclosing plate 103 arranged around the horizontal plane of the common chip 300, the chip top plate 101 on the top of the common chip 200, and the first heat dissipation shoulder 102 together form a closed second heat-generating space cavity. In a preferred embodiment, the chip top plate 101 is provided a heat insulating layer when a chip is disposed directly above the common chip 200. In a preferred embodiment, the chip top plate 101 is provided with a heat dissipation package layer, when no chip is arranged directly above the common chip 200.

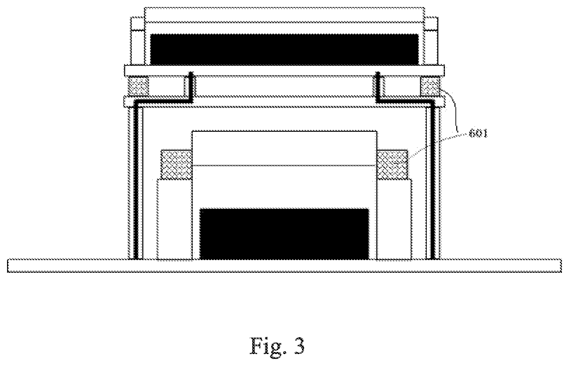

In a preferred embodiment, referring to FIG. 3, the power heat dissipation shoulder and the second heat dissipation shoulder comprise several micro-flow channels, wherein the number and size of pipes of the micro-flow channels of the power heat dissipation shoulder 110 and the second heat dissipation shoulder 106 are configured together in the present application, to ensure that the power heat dissipation shoulder 110 meets the minimum heat dissipation requirement of the first heat-generating space cavity, that is, first determine the limit heat-generating power Pm of the first heat-generating space cavity;

determine the self-heat dissipation power paᵢ of each pipe in its micro-flow channels for the power heat dissipation shoulder 110, determine the external heat dissipation power pbᵢ of each pipe in its micro-flow channels for the power heat dissipation shoulder 110, and determine the number n1 of pipes in its micro-flow channels for the power heat dissipation shoulder 110; determine a self-heat dissipation power pcᵢ of each pipe in its micro-flow channels for the second heat dissipation shoulder 106, determine an external heat dissipation power pdᵢ of each pipe in its micro-flow channels for the second heat dissipation shoulder 106, and determine the number n2 of pipe in its micro-flow channels of the second heat dissipation shoulder 106; then determine the thermal energy power attenuation rate f1 from a spatial position of the power heat dissipation shoulder 110 to a spatial position of the second heat dissipation shoulder 106; then, the number and size of the pipes in its the micro-flow channel of the power heat dissipation shoulder 110 and the second heat dissipation shoulder 106 that are configured together specifically meet:

P_{M}*M1−Σᵢ₌₁ⁿ¹(paᵢ+pbᵢ)≤0;

(P_{M}=Σᵢ₋₁ⁿ¹(pcᵢ+pdᵢ))*)1−f1)*M2≤Σᵢ₌₁ⁿ¹(paᵢ+pbᵢ);

where i is a variable, M1 is the first acceptable parameter, M2 is the second acceptable parameter, the first acceptable parameter represents the ratio of the limit heat-generating power of the first heat-generating space cavity to the maximum power of an acceptable thermal environment in the first heat-generating space cavity, the second acceptable parameter represents the ratio of the power of indirect heating of other devices by the remaining heat after the heat generated in the first heat-generating space cavity is dissipated by the second heat-dissipating shoulder 106 to the maximum power of the thermal environment acceptable to the other devices. Therefore, the present application can ensure that the heat dissipation of the power device will not have an indirect impact on other devices on the basis of not exceeding the maximum power of the acceptable thermal environment in the first heat-generating space cavity. That is to say, even if the heat dissipation of the power device will indirectly affect other devices, it is within the acceptable range of other devices.

In a preferred embodiment, referring to FIG. 3, the power heat dissipation shoulder and the second heat dissipation shoulder comprise several micro-flow channels, wherein the number and size of pipes of the micro-flow channels of the power heat dissipation shoulder 110 and the second heat dissipation shoulder 106 are configured together in the present application, to ensure that the power heat dissipation shoulder 110 meets the minimum heat dissipation requirement of the first heat-generating space cavity, that is, first determine the limit heat-generating power P_{M} of the first heat-generating space cavity; determine the convolution equivalent efficiency peᵢ of the self-heat dissipation power paᵢ of each pipe in its micro-flow channels and the external heat dissipation power pbᵢ of each pipe in its micro-flow channels for the power heat dissipation shoulder 110 , and determine the nurriber n1 of micro-flow channels of the power heat dissipation shoulder 110; determine the convolution equivalent efficiency prᵢ of the self-heat dissipation power pcᵢ of each pipe in its micro-flow channels and the external heat dissipation power pdᵢ of each pipe in its micro-flow channels for the second heat dissipation shoulder 106, and the number n2 of the pipes of micro-flow channels of the second heat dissipation shoulder 106; then determine the thermal energy power attenuation rate f1 from a spatial position of the power heat dissipation shoulder 110 to a spatial position of the second heat dissipation shoulder 106; then, the number and size of the pipes in its the micro-flow channel of the power heat dissipation shoulder 110 and the second heat dissipation shoulder 106 that are configured together specifically meet:

PM*M1=Σᵢ₌₁ⁿ¹(peᵢ)≤0;

(PM−Σᵢ₌₁ⁿ¹(prᵢ))*(1−f1)*M2≤Σᵢ₌₁ⁿ¹(peᵢ);

where i is a variable, M1 is the first acceptable parameter, M2 is the second acceptable parameter, the first acceptable parameter represents the ratio of the limit heat-generating power of the first heat-generating space cavity to the maximum power of an acceptable thermal environment in the first heat-generating space cavity, the second acceptable parameter represents the ratio of the power of indirect heating of other devices by the remaining heat after the heat generated in the first heat-generating space cavity is dissipated by the second heat-dissipating shoulder 106 to the maximum power of the thermal environment acceptable to the other devices. In the embodiment of the present application, the previous simple summation can be replaced by the equivalent efficiency of the convolution of the self-heat dissipation power of the pipe and the external heat dissipation power of the pipe, so that the corresponding actual efficiency can be calculated more accurately, and the control parameters are accurate and the effect is better. The self-heat dissipation power of the pipe in this application specifically refers to the efficiency of the pipe directly dissipating heat through liquid flow. The external heat dissipation power of the pipe in this application specifically refers to the efficiency of indirect heat dissipation through non-liquid flow after the pipe absorbs heat. Obviously, convolving the two efficiencies can better characterize the overall efficiency.

The above are only the preferred embodiments of the present application, and are not intended to limit the present application. Therefore, any modification, equivalent replacement, improvement, etc. made to the above embodiments according to the technical practice of the present application still fall within the scope of the technical solution of the present application.

What is claimed is:

1. A multi-chip 3D stacking packaging structure with high heat dissipation efficiency, comprising a wiring board, a power device fixed on the wiring board, and a lateral heat insulating plate is arranged around the horizontal plane of the power device, wherein a heat insulating layer is arranged directly above the power device, and the height of the heat insulating layer is higher than that of the lateral heat insulating plate, a power heat dissipation shoulder is arranged on the top of the lateral heat insulating plate, and the top of the power heat dissipation shoulder is connected with the edge of the heat insulating layer, the wiring board at the bottom of the power device, the lateral heat insulating plate arranged around the horizontal plane of the power device, the heat insulating layer on the top of the power device and the power heat dissipation shoulder together form a closed first heat-generating space cavity, a long adapter support channel is arranged on the wiring board on the side of the horizontal surface of the lateral heat insulating plate that is away from the power device, a first adapter plate is arranged on the top of the long adapter support channel, the top of the first adapter plate is fixed with a second adapter plate through a short adapter support channel, and the top of the second adapter plate is fixed with a common chip, the common chip is electrically connected to an adapter metal wire through the second adapter plate, and the adapter metal wire is electrically connected to the wiring board through the short adapter support channel, the first adapter plate, and the long adapter support channel.

2. The multi-chip 3D stacking packaging structure with high heat dissipation efficiency according to claim 1, wherein a second heat dissipation shoulder is arranged on the edge of the first adapter plate, and the top of the second heat dissipation shoulder is connected to the top of the second adapter plate.

3. The multi-chip 3D stacking packaging structure with high heat dissipation efficiency according to claim 2, wherein a chip enclosing plate is arranged around horizontal plane of the common chip, and a chip top plate is arranged directly above the common chip, and the height of the chip top plate is higher than that of the chip enclosing plate, a first heat dissipation shoulder is arranged on the top of the chip enclosing plate, and the top of the first heat dissipation shoulder is connected to the chip top plate, the second adapter plate at the bottom of the common chip, the chip enclosing plate arranged around the horizontal plane of the common chip, the chip top plate on the top of the common chip, and the first heat dissipation shoulder together form a closed second heat-generating space cavity.

4. The multi-chip 3D stacking packaging structure with high heat dissipation efficiency according to claim 3, wherein the chip top plate is provided with a heat insulating layer when the chip is arranged directly above the common chip.

5. The multi-chip 3D stacking packaging structure with high heat dissipation efficiency according to claim 3, wherein the chip top plate is provided with a heat dissipation package layer, when no chip is arranged directly above the common chip.

6. The multi-chip 3D stacking packaging structure with high heat dissipation efficiency according to claim 5, wherein the power heat dissipation shoulder and the second heat dissipation shoulder comprise several micro-flow channels, wherein the number and size of pipes of the micro-flow channels of the power heat dissipation shoulder and the second heat dissipation shoulder are configured together to ensure that the power heat dissipation shoulder meets the minimum heat dissipation requirement of the first heat-generating space cavity, that is, first determine the limit heat-generating power P_{M} of the first heat-generating space cavity;
determine the self-heat dissipation power pa; of each pipe in its micro-flow channels for the power heat dissipation shoulder, determine the external heat dissipation power pbᵢ of each pipe in its micro-flow channels for the power heat dissipation shoulder, and determine the number n1 of pipes in its micro-flow channels for the power heat dissipation shoulder; determine a self-heat dissipation power pcᵢ of each pipe in its micro-flow channels for the second heat dissipation shoulder, determine an external heat dissipation power pdᵢ of each pipe in its micro-flow channels for the second heat dissipation shoulder, and determine the number n2 of pipe in its micro-flow channels of the second heat dissipation shoulder; then determine the thermal energy power attenuation rate f1 from a spatial position of the power heat dissipation shoulder to a spatial position of the second heat dissipation shoulder; then, the number and size of the pipes in its the micro-flow channel of the power heat dissipation shoulder and the second heat dissipation shoulder that are configured together specifically meet:
P_{M}*M1−Σᵢ₌₁ⁿ¹(paᵢ+pbᵢ)≤0;
(P_{M}=Σᵢ₋₁ⁿ¹(pcᵢ+pdᵢ))*)1−f1)*M2≤Σᵢ₌₁ⁿ¹(paᵢ+pbᵢ);
where i is a variable, M1 is the first acceptable parameter, M2 is the second acceptable parameter, the first acceptable parameter represents the ratio of the limit heat-generating power of the first heat-generating space cavity to the maximum power of an acceptable thermal environment in the first heat-generating space cavity, the second acceptable parameter represents the ratio of the power of indirect heating of other devices by the remaining heat after the heat generated in the first heat-generating space cavity is dissipated by the second heat-dissipating shoulder to the maximum power of the thermal environment acceptable to the other devices.

7. The multi-chip 3D stacking packaging structure with high heat dissipation efficiency according to claim 5, wherein the power heat dissipation shoulder and the second heat dissipation shoulder comprise several micro-flow channels, wherein the number and size of pipes of the micro-flow channels of the power heat dissipation shoulder and the second heat dissipation shoulder are configured together to ensure that the power heat dissipation shoulder meets the minimum heat dissipation requirement of the first heat-generating space cavity, that is, first determine the limit heat-generating power P_{M} of the first heat-generating space cavity;
determine the convolution equivalent efficiency peᵢ of the self-heat dissipation power paᵢ of each pipe in its micro-flow channels and the external heat dissipation power pbᵢ of each pipe in its micro-flow channels for the power heat dissipation shoulder, and determine the number n1 of micro-flow channels of the power heat dissipation shoulder; determine the convolution equivalent efficiency prᵢ of the self-heat dissipation power pcᵢ of each pipe in its micro-flow channels and the external heat dissipation power pdᵢ of each pipe in its micro-flow channels for the second heat dissipation shoulder, and the number n2 of the pipes of micro-flow channels of the second heat dissipation shoulder; then determine the thermal energy power attenuation rate f1 from a spatial position of the power heat dissipation shoulder to a spatial position of the second heat dissipation shoulder; then, the number and size of the pipes in its the micro-flow channel of the power heat dissipation shoulder and the second heat dissipation shoulder that are configured together specifically meet:
PM*M1=Σᵢ₌₁ⁿ¹(peᵢ)≤0;
(PM−Σᵢ₌₁ⁿ¹(prᵢ))*(1−f1)*M2≤Σᵢ₌₁ⁿ¹(peᵢ);
where i is a variable, M1 is the first acceptable parameter, M2 is the second acceptable parameter, the first acceptable parameter represents the ratio of the limit heat-generating power of the first heat-generating space cavity to the maximum power of an acceptable thermal environment in the first heat-generating space cavity, the second acceptable parameter represents the ratio of the power of indirect heating of other devices by the remaining heat after the heat generated in the first heat-generating space cavity is dissipated by the second heat-dissipating shoulder to the maximum power of the thermal environment acceptable to the other devices.

8. A packaging method of the multi-chip 3D stack packaging structure with high heat dissipation efficiency, the packaging method comprises the following steps: arranging a power device on a wiring board, arranging a lateral heat insulating plate around the horizontal plane of the power device, and then arranging a power heat dissipation shoulder on the top of the lateral heat insulating plate, and then arranging a heat insulating layer between the power heat dissipation shoulders, after that, arranging a long adapter support channel on the wiring board on the side of the horizontal plane of the lateral heat insulating plate that is away from the power device, and reserving an adapter metal wire on the long adapter support channel; arranging a first adapter plate, a short adapter support channel and a second adapter plate on the top of the long transfer support channel, reserving the adapter metal wires on the short adapter support channel and the first adapter plate; arranging a second heat dissipation shoulder between the first adapter plate and the second adapter plate; and then arranging common chip, chip enclosing plate, first heat dissipation shoulder and chip top plate on the second adapter plate.
